(19) United States
(12) Patent Application Publication
(10) Pub. No.: US 2024/0291493 A1
(43) Pub. Date: Aug. 29, 2024

(54) PHASE LOCKED LOOP CIRCUIT

(71) Applicant: LAPIS Technology Co., Ltd., Yokohama (JP)

(72) Inventor: Atsushi NAGAYAMA, Yokohama (JP)

(73) Assignee: LAPIS Technology Co., Ltd., Yokohama (JP)

(21) Appl. No.: 18/581,310

(22) Filed: Feb. 19, 2024

(30) Foreign Application Priority Data
Feb. 28, 2023 (JP) 2023-030361

(51) Int. Cl. H03L 7/089; H03L 7/091; H03L 7/099

(52) U.S. Cl. CPC H03L 7/0891; H03L 7/091; H03L 7/099

(57) ABSTRACT

A deadlock detection circuit 20 determines that deadlock occurs, sets a switching signal 106 to H level when a control voltage 104 exceeds an upper limit set in advance, and set the switching signal to L level when the control voltage 104 is lower than a lower limit set in advance. When the switching signal 106 reaches H level, multiplexers 12, 13 perform switching, so that, in place of a reference clock signal 101, an L level signal is input to a phase frequency detector 14, and, in place of a feedback clock signal 107, the reference clock signal 101 is input to the phase frequency detector 14.

### CROSS-REFERENCE TO RELATED APPLICATION

This application claims priority under 35 USC 119 from Japanese Patent application No. 2023-030361 filed on Feb. 28, 2023, the disclosure of which is incorporated by reference herein.

### BACKGROUND

### Technical Field

The disclosure relates to a phase locked loop (PLL) circuit.

### Related Art

A phase locked loop (PLL) circuit for generating output signals of various frequencies based on a reference frequency has been used widely (see, for example, Japanese Patent Application Laid-open No. 2004-7433).

The PLL circuit includes a voltage controlled oscillator (VCO) formed to change the oscillation frequency in accordance with a control voltage, and is configured to obtain an output signal having a desired frequency by changing the control voltage.

In recent years, the required output frequency of such PLL circuits has increased, and output signals with a wide frequency band have been generated. Therefore, there may be cases where operation conditions and settings with which peripheral circuits do not operate are included in the frequency properties of VCOs.

Therefore, in the PLL circuit, deadlock may occur when a frequency exceeding the operation range is set, and, unless reset externally, the PLL circuit cannot return to the normal operation state.

The disclosure provides a PLL circuit able to automatically return to the normal operation state if an operable frequency is set, even if deadlock occurs due to an unintentional setting that exceeds the operable frequency.

### SUMMARY

A phase locked loop (PLL) circuit according to an aspect of the disclosure includes: a voltage controlled oscillator, generating an output signal having an oscillation frequency in accordance with a control voltage that is input; a frequency division circuit, performing frequency division on a frequency of the output signal generated by the voltage controlled oscillator by using a frequency division ratio that is set; a phase comparator, detecting a phase difference between the output signal on which frequency division has been performed by the frequency division circuit and a reference signal having a frequency set in advance, and outputting a raising instruction signal or a dropping instruction signal in accordance to the phase difference that is detected; a charge pump circuit, raising or dropping an output voltage based on the raising instruction signal or the dropping instruction signal; a filter circuit, smoothing the output voltage from the charge pump circuit and outputting a smoothed output voltage, as the control voltage, to the voltage controlled oscillator; a deadlock detection circuit, setting a switching signal to be active in a case where the control voltage exceeds an upper limit set in advance, and setting the switching signal to be inactive in a case where the control voltage is lower than a lower limit set in advance; and a switching circuit, performing switching so that, in a case where the switching signal is inactive, responsive to the output signal on which frequency division has been performed by the frequency division circuit and the reference signal being input to the phase comparator to detect the phase difference and a frequency difference and the switching signal becoming active, a low level signal is input in place of the reference signal, and the reference signal is input in place of the output signal on which frequency division has been performed by the frequency division circuit.

In addition, in the PLL circuit according to an embodiment of the disclosure, it may also be configured that the deadlock detection circuit is formed by: a first generation circuit, generating a first signal in a case where the control voltage reaches or exceeds an upper limit voltage set in advance; a second generation circuit, generating a second signal in a case where the control voltage drops to or below a lower limit voltage set in advance; and a flip-flop circuit, setting the first signal as a clock input, and setting the second signal as a reset input, wherein a high level signal is connected with an input, and an output is set as the switching signal.

Moreover, in the PLL circuit according to an embodiment of the disclosure, it may also be configured that the first generation circuit has a first transistor set to be OFF responsive to the control voltage reaching or exceeding the upper limit voltage set in in advance, and sets the first signal to high level by setting the first transistor to be OFF, and the second generation circuit has a second transistor set to be OFF responsive to the control voltage dropping to or below the lower limit voltage set in in advance, and sets the second signal to high level by setting the second transistor to be OFF.

### BRIEF DESCRIPTION OF THE DRAWINGS

FIG. 1 is a block diagram illustrating a configuration of a PLL circuit 10 according to an embodiment of the disclosure.

FIG. 2 is a diagram for illustrating an operation of a phase frequency detector 14.

FIG. 3 is a circuit diagram illustrating a specific circuit configuration of a deadlock detection circuit 20.

FIG. 4 is a diagram for illustrating an input switching operation of the phase frequency detector 14.

FIG. 5 is a flowchart for illustrating an operation of the PLL circuit 10 according to an embodiment.

FIG. 6 is a timing chart for illustrating the operation of the PLL circuit 10 according to an embodiment.

### DETAILED DESCRIPTION

According to the disclosure, a PLL circuit able to automatically return to the normal operation state if an operable frequency is set, even if deadlock occurs due to an unintentional setting that exceeds the operable frequency can be provided.

In the following, the embodiments of the disclosure will be described in detail with reference to the drawings.

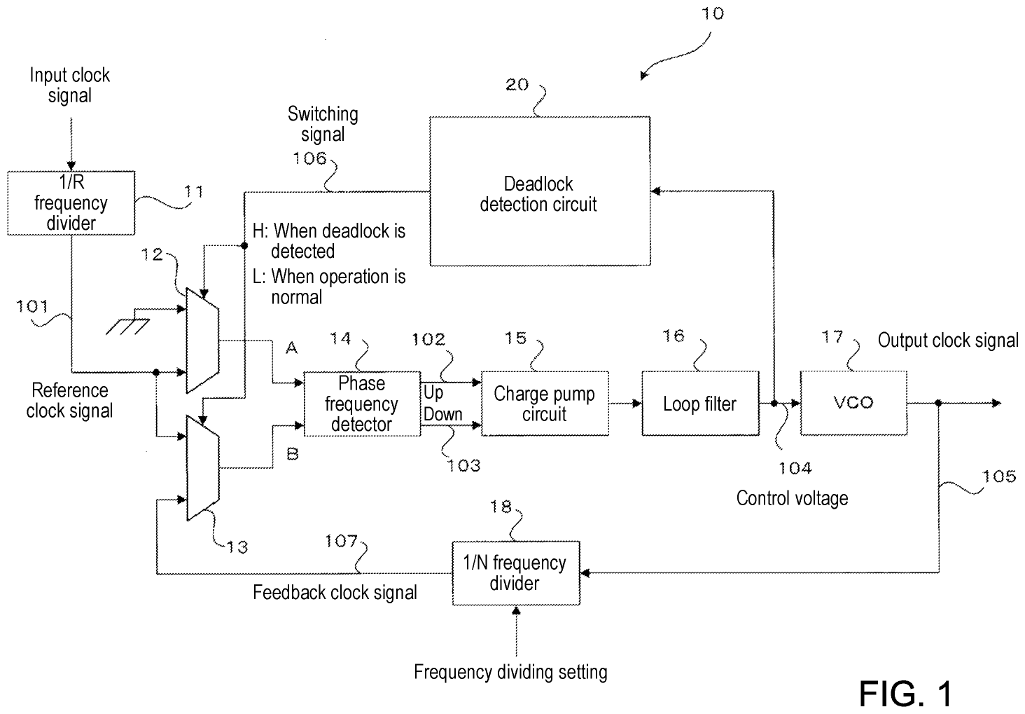

FIG. 1 is a block diagram illustrating a configuration of a PLL circuit 10 according to an embodiment of the disclosure.

As shown in FIG. 1, the PLL circuit 10 according to the embodiment is formed by a 1/R frequency divider 11, multiplexers 12, 13, a phase frequency detector (PFD) 14, a charge pump circuit 15, a loop filter (LPF) 16, a voltage controlled oscillator (VCO) 17, a 1/N frequency divider 18, and a deadlock detection circuit 20.

The 1/R frequency divider generates a reference clock signal 101 by performing frequency division on an input clock signal by using a frequency division ratio set in advance.

The deadlock detection circuit 20 is a circuit that monitors a control voltage 104 for controlling an oscillation frequency of the VCO 17 to detect that deadlock occurs in the case where the control voltage 104 exceeds a voltage range set in advance. Specifically, in the case where the control voltage 104 exceeds an upper limit set in advance, the deadlock detection circuit 20 determines that deadlock occurs and that a switching signal 106 is at a high level (referred to as “H level” in the following) that is active. Meanwhile, in the case where the control voltage 104 is lower than a lower limit set in advance, the deadlock detection circuit 20 sets the switching signal 106 to a low level (referred to as “L level” in the following) that is inactive.

In addition, in the case where the switching signal 106 is at L level, the multiplexers 12, 13 function as a switching circuit that inputs a feedback clock signal 107 and the reference clock signal 101 into the phase frequency detector 14 so that a phase difference and a frequency difference are detected, the feedback clock signal 107 being an output signal on which frequency division has been performed by the 1/N frequency divider 18, and the reference clock signal 101 being provided from the 1/R frequency divider 11. In addition, when the switching signal 106 becomes H level, the multiplexers 12, 13 perform switching, so that, in place of the reference clock signal 101, an L level signal is input to the phase frequency detector 14, and, in place of the feedback clock signal 107 on which frequency division has been performed by the 1/N frequency divider 18, the reference clock signal 101 is input to the phase frequency detector 14.

Specifically, in the case where the switching signal 106 is at L level, the multiplexer 12 outputs the reference clock signal 101 to an input A of the phase frequency detector 14, and in the case where the switching signal 106 is at H level, the multiplexer 12 outputs the L level signal to the input A of the phase frequency detector 14. In addition, in the case where the switching signal 106 is at L level, the multiplexer 13 outputs the feedback clock signal 107 from the 1/N frequency divider 18 to an input B of the phase frequency detector 14, and in the case where the switching signal 106 is at H level, the multiplexer 13 outputs the reference clock signal 101 to the input B of the phase frequency detector 14.

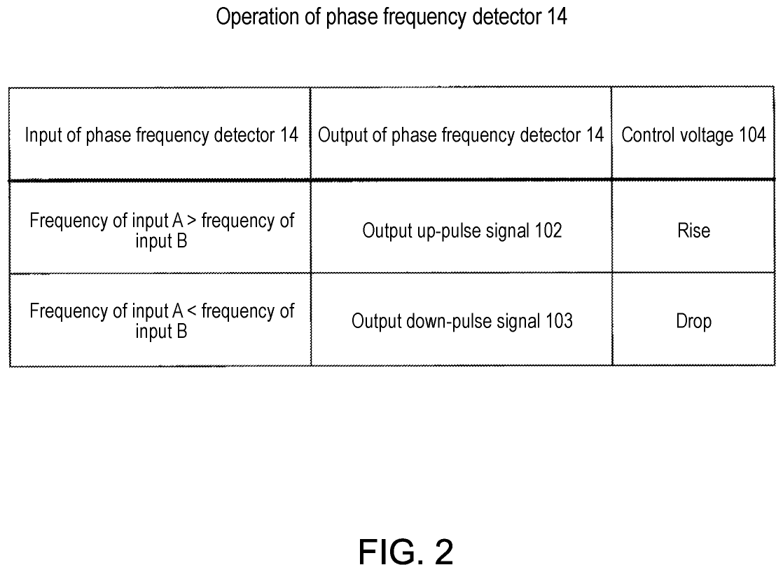

Then, the operation of the phase frequency detector 14 is described with reference to FIG. 2. As shown in FIG. 2, the phase frequency detector 14 outputs an up-pulse signal 102, which is a raising instruction signal, to the charge pump circuit 15 in the case where the frequency of the input A is higher than the frequency of the input B. In addition, as shown in FIG. 2, the phase frequency detector 14 outputs a down-pulse signal 103, which is a dropping instruction signal, to the charge pump circuit 15 in the case where the frequency of the input B is higher than the frequency of the input A.

The charge pump circuit 15 increases or decreases the output voltage based on the up-pulse signal 102 or the down-pulse signal 103. Specifically, when the up-pulse signal 102 is input, the charge pump circuit 15 applies a current so as to raise the output voltage, and when the down-pulse signal 103 is input, the charge pump circuit 15 draws a current so as to lower the output voltage.

The loop filter (LPF) 16 is a filter circuit that smooths the output voltage from the charge pump circuit 15 to output the smoothed voltage, as the control voltage 104, to the VCO 17.

With the circuit configuration formed as the above, when the up-pulse signal 102 is output from the phase frequency detector 14, the control voltage 104 rises, and when the down-pulse signal 103 is output from the phase frequency detector 14, the control voltage 104 drops.

The voltage controlled oscillator (VCO) 17 generates an output clock signal 105 having an oscillation frequency in accordance with the control voltage 104 input from the loop filter 16.

The 1/N frequency divider 18 is a frequency division circuit that performs frequency division on the frequency of the output clock signal 105 generated by the VCO 17 by using a frequency division ratio N that is set, and outputs the frequency-divided signal as the feedback clock signal 107.

In addition, in the PLL circuit 10, at the time of normal operation during which deadlock does not occur, the reference clock signal 101 is input as the input A of the phase frequency detector 14, and the feedback clock signal 107 from the 1/N frequency divider 18 is input as the input B. Therefore, the phase frequency detector 14 functions as a phase comparator that detects the phase difference between the feedback clock signal 107 on which frequency division has been performed by the 1/N frequency divider 18 and the reference clock signal 101 as the reference signal of the frequency set in advance, and outputs one of the up-pulse signal 102 and the down-pulse signal 103 in accordance with the detected phase difference.

By performing such operation, in the PLL circuit 10 according to the embodiment, the frequency of the output clock signal 105 is controlled through a frequency division setting performed with respect to the 1/N frequency divider 18. For example, in the case where the frequency division ratio N set with respect to the 1/N frequency divider 18 is 10, the frequency of the output clock signal 105 is 10 times the frequency of the reference clock signal 101.

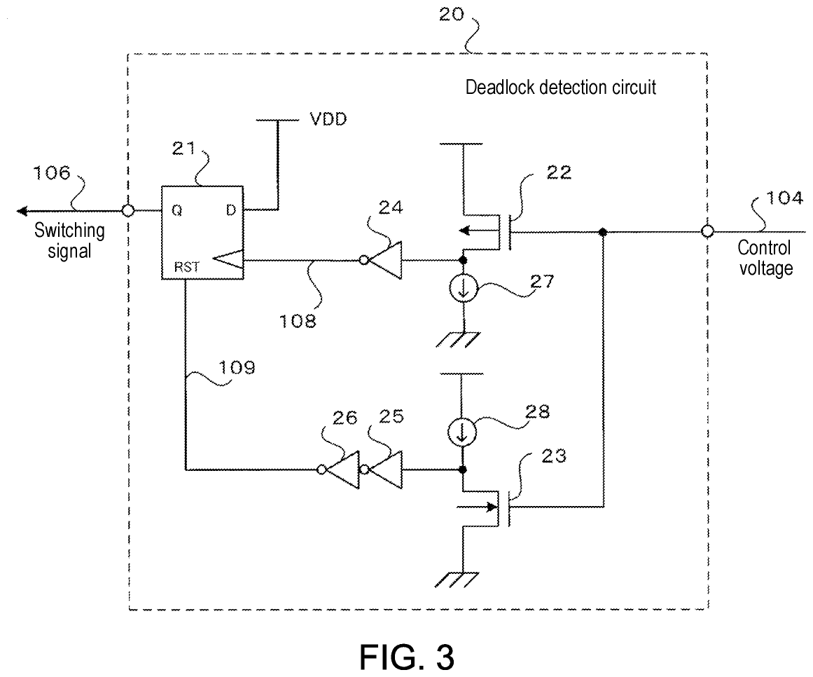

Then, a detailed circuit configuration of the deadlock detection circuit 20 shown in FIG. 1 is shown in the circuit diagram of FIG. 3.

As shown in FIG. 3, the deadlock detection circuit 20 is formed by a flip-flop (FF) circuit 21, a P channel type field effect transistor (FET) 22, an N channel type FET 23, inverter circuits 24 to 26, and current sources 27, 28.

With the P channel type FET 22, the current source 27, and the inverter circuit 24, a first generation circuit is formed. The first generation circuit generates an upper limit detection signal 108, which is a first signal, in the case where the control voltage 104 reaches or exceeds an upper limit voltage set in advance.

Then, with the N channel type FET 23, the current source 28, and the inverter circuits 25, 26, a second generation circuit is formed. The second generation circuit generates a lower limit detection signal 108, which is a second signal, in the case where the control voltage 104 drops to or below a lower limit voltage set in advance.

In addition, the flip-flop circuit 21 is connected so that the upper limit detection signal 108 from the inverter circuit 24 is set as a clock input, the lower limit detection signal 109 from the inverter circuit 26 is set as a reset input (RST), VDD, which is an H level signal, is connected with an input D, and an output Q is set as the switching signal 106.

In the P channel FET 22, the gate is connected with the control voltage 104, the source is connected with the power voltage VDD, and the drain is grounded via the current source 27. In addition, in the N channel FET 23, the gate is connected with the control voltage 104, the source is grounded, and the drain is connected with the power voltage VDD via the current source 28. In addition, the inverter circuit 24 inverts the logic of the voltage of the drain of the P channel type FET 22 and makes the output as the upper limit detection signal 108 to the clock input of the flip-flop circuit 21. In addition, the inverter circuit 25 inverts the logic of the voltage of the drain of the N channel type FET 23, and the inverter circuit 26 further inverts the logic and makes the output as the lower limit detection signal 109 to the reset input of the flip-flop circuit 21.

That is, the first generation circuit has the P channel type FET 22, which serves as a first transistor that is set to be OFF when the control voltage 104 reaches or exceeds the upper limit voltage set in advance. With the P channel type FET 22 being set to be OFF, the first generation circuit sets the upper limit detection signal 108 to H level.

The upper limit voltage at the time when the deadlock detection circuit 20 monitors the voltage range of the control voltage 104 is set to a voltage obtained by subtracting the threshold voltage of the P channel type FET 22 from the power voltage. In addition, the lower limit voltage is the threshold voltage of the N channel type FET 23.

In addition, in the case where deadlock occurs, the control voltage 104 sticks to a voltage at which the VCO 17 generates the output clock signal 105 of a high frequency, that is, the control voltage 104 sticks to the power voltage side. Therefore, by making the upper limit voltage as close to the power voltage as possible, the voltage range of the control voltage 104 usable in normal operation is expanded. Specifically, by adding one stage of the N channel type FET between the gate of the P channel type FET 22 and the control voltage 104, it is possible to shift the level by the amount of the threshold voltage of the N channel type FET. In addition, as the voltage range of the control voltage 104 expands, it is possible to expand the frequency range of the output clock signal 105 that is generated.

In addition, when the upper limit detection signal 108 of the clock input is at H level, the flip-flop circuit 21 outputs the H level signal of the input D to the output Q. As a result, the switching signal 106 is set to H level.

In addition, the second generation circuit has the N channel type FET 23, which serves as a second transistor that is set to be OFF when the control voltage 104 drops to or below the lower limit voltage set in advance. With the N channel type FET 23 being set to be OFF, the second generation circuit sets the lower limit detection signal 109 to H level.

In addition, when the lower limit detection signal 109 of the reset input is at H level, the flip-flop circuit 21 sets the output Q at H level to L level. As a result, the switching signal 106 is set to L level.

With the above circuit configuration, the deadlock detection circuit 20 operates so as to set the switching signal 106 to H level when the control voltage 104 reaches or exceeds the upper limit voltage, and set the switching signal 106 set at H level to L level when the control voltage 104 drops to or below the lower limit voltage.

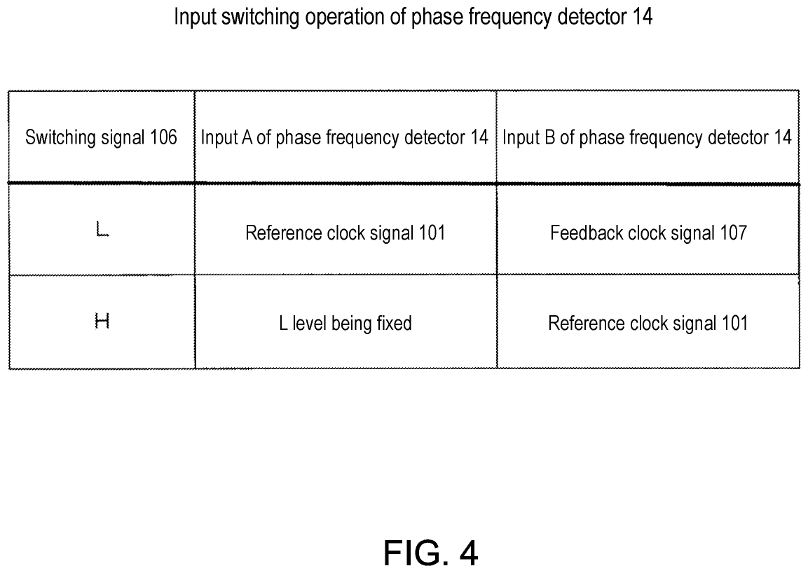

In addition, by changing the logic of the switching signal 106 from the deadlock detection circuit 20, the input of the phase frequency detector 14 is switched as shown in FIG. 4.

Specifically, in the case where the switching signal 106 is at L level, the reference clock signal 101 is input to the input A of the phase frequency detector 14, and the feedback clock signal 107 is input to the input B of the phase frequency detector 14. Therefore, in the PLL circuit 10, normal operation is performed, and the output clock signal 105 is generated based on the frequency division ratio set in the 1/N frequency divider 18.

Then, when the control voltage 104 reaches or exceeds the upper limit voltage and the deadlock detection circuit 20 detects that deadlock occurs, the switching signal 106 becomes H level. Then, the input A of the phase frequency detector 14 is fixed at L level, and switching is performed so that the reference clock signal 101 is input to the input B of the phase frequency detector 14. That is, a state in which the frequency of the input B is constantly higher than the frequency of the input A is maintained. As a result, the phase frequency detector 14 keeps outputting the down-pulse signal 103, the charge pump circuit 15 lowers the output voltage, and the control voltage 104 also keeps dropping.

Then, since the deadlock detection circuit 20 sets the switching signal 106 back to L level when the control voltage 104 drops to or below the lower limit voltage, the reference clock signal 101 is input to the input A of the phase frequency detector 14, the feedback clock signal 107 is input to the input B of the phase frequency detector 14, and the operation automatically returns to the operation at the normal time. Then, the control voltage 104 rises until the output clock signal 105 reaches a frequency based on the frequency division ratio N set in the 1/N frequency divider 18, and when the frequency of the reference clock signal 101 and the frequency of the feedback clock signal 107 conform to each other, a locked state is achieved.

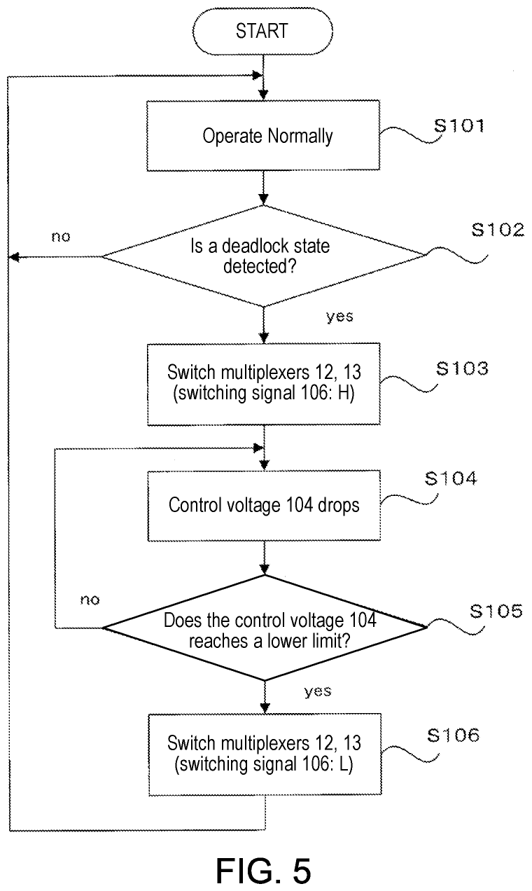

The operation in the PLL circuit 10 according to the embodiment is shown in the flowchart of FIG. 5.

In the PLL circuit 10, the normal operation at the normal time (S101) is performed until deadlock is detected in the deadlock detection circuit 20 (i.e., until Yes is determined in Step S102) (Step S101).

In addition, when deadlock is detected in the deadlock detection circuit 20 (Yes in Step S102), the switching signal 106 becomes H level and the switching of the multiplexers 12, 13 is performed (Step S103).

As a result, with the phase frequency detector 14 keeping outputting the down-pulse signal 103, the control voltage 104 keeps dropping (Step S104). Then, when the control voltage 104 reaches the lower limit voltage (yes in Step S105), the deadlock detection circuit 20 sets the switching signal to L level.

Therefore, the switching of the multiplexers 12, 13 is performed again (Step S106), and the PLL circuit 10 returns to the normal operation at the normal time.

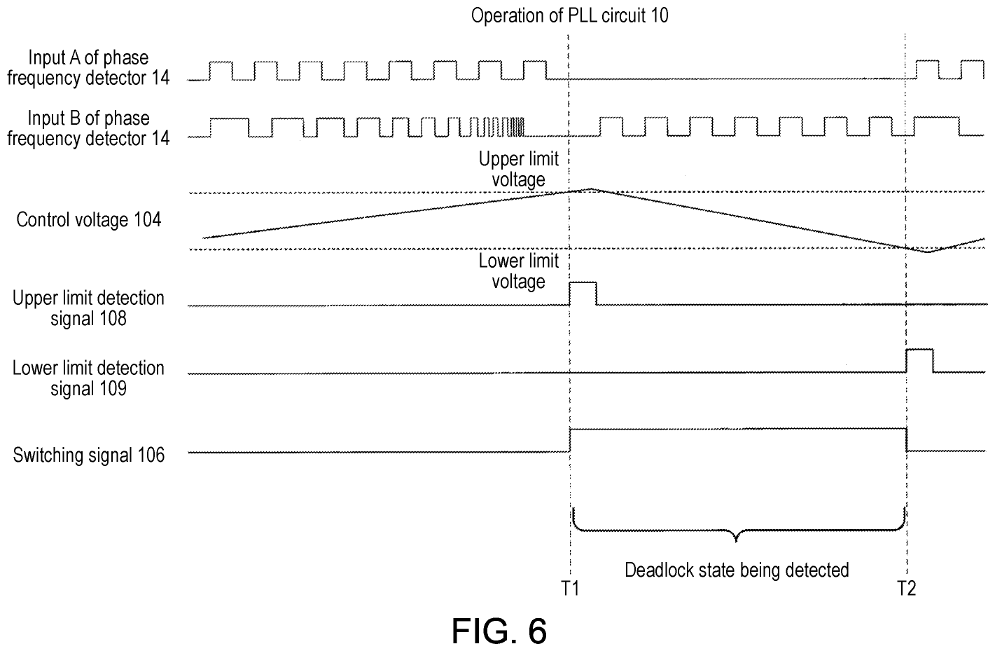

Lastly, the operation in the PLL circuit 10 according to the embodiment is shown in a timing chart of FIG. 6.

FIG. 6 illustrates the case where the frequency division ratio is set outside the operation frequency range with respect to the 1/N frequency divider 18 and the control voltage 104 rises to exceed the upper limit voltage.

Until the deadlock detection circuit 20 detects deadlock, the reference clock signal 101 is input to the input A of the phase frequency detector 14, and the feedback clock signal 107 is input to the input B.

In addition, when the control voltage 104 exceeds the upper limit voltage at a timing T1, in the deadlock detection circuit 20, the P channel type FET 22 becomes OFF, and the upper limit detection signal 108 becomes H level. As a result, the deadlock detection circuit 20 sets the switching signal 106 from L level to H level.

Then, since the down-pulse signal 103 keeps being output from the phase frequency detector 14, the control voltage 104 drops. When the control voltage 104 drops to or below the upper limit voltage, the P channel type FET 22 becomes ON, and the upper limit detection signal 108 returns to L level. However, even in such state, the switching signal 106 is maintained at H level.

In addition, when the control voltage 104 keeps dropping and drops below the lower limit voltage at a timing T2, in the deadlock detection circuit 20, the N channel type FET 23 becomes OFF and the lower limit detection signal 109 becomes H level. As a result, the deadlock detection circuit 20 sets the switching signal 106 from H level to L level. Then, the phase frequency detector 14 returns to normal operation, and the control voltage 104 rises, so that the output clock signal 105 reaches the frequency based on the frequency division ratio that is set. When the control voltage 104 rises to reach or exceed the lower limit voltage, the N channel type FET 23 becomes ON, and the lower limit detection signal 109 becomes L level.

In the PLL circuit 10 of the embodiment, by performing the above operation, even though deadlock occurs due to an unintentional setting of the frequency division ratio that exceeds the operable frequency, if an operable frequency is set, it is not necessary to externally perform a reset operation, etc., and it is possible to automatically return to the normal operation state.

Also, in the PLL circuit 10 of the embodiment, by using only the deadlock detection circuit 20 in a simple circuit configuration as shown in FIG. 3 and the multiplexers 12, 13, it is possible to automatically return to normal operation from deadlock.

What is claimed is:

1. A phase locked loop (PLL) circuit, comprising:
a voltage controlled oscillator, generating an output signal having an oscillation frequency in accordance with a control voltage that is input;
a frequency division circuit, performing frequency division on a frequency of the output signal generated by the voltage controlled oscillator by using a frequency division ratio that is set;
a phase comparator, detecting a phase difference between the output signal on which frequency division has been performed by the frequency division circuit and a reference signal having a frequency set in advance, and outputting a raising instruction signal or a dropping instruction signal in accordance to the phase difference that is detected;
a charge pump circuit, raising or dropping an output voltage based on the raising instruction signal or the dropping instruction signal;
a filter circuit, smoothing the output voltage from the charge pump circuit and outputting a smoothed output voltage, as the control voltage, to the voltage controlled oscillator;
a deadlock detection circuit, setting a switching signal to be active in a case where the control voltage exceeds an upper limit set in advance, and setting the switching signal to be inactive in a case where the control voltage is lower than a lower limit set in advance; and
a switching circuit, performing switching so that, in a case where the switching signal is inactive, responsive to the output signal on which frequency division has been performed by the frequency division circuit and the reference signal being input to the phase comparator to detect the phase difference and a frequency difference and the switching signal becoming active, a low level signal is input in place of the reference signal, and the reference signal is input in place of the output signal on which frequency division has been performed by the frequency division circuit

2. The PLL circuit as claimed in claim 1, wherein the deadlock detection circuit is formed by:
a first generation circuit, generating a first signal in a case where the control voltage reaches or exceeds an upper limit voltage set in advance;
a second generation circuit, generating a second signal in a case where the control voltage drops to or below a lower limit voltage set in advance; and
a flip-flop circuit, setting the first signal as a clock input, and setting the second signal as a reset input, wherein a high level signal is connected with an input, and an output is set as the switching signal.

3. The PLL circuit as claimed in claim 2, wherein the first generation circuit has a first transistor that is set to be OFF responsive to the control voltage reaching or exceeding the upper limit voltage set in advance, and sets the first signal to high level by setting the first transistor to be OFF, and
the second generation circuit has a second transistor that is set to be OFF responsive to the control voltage dropping to or below the lower limit voltage set in in advance, and sets the second signal to high level by setting the second transistor to be OFF.
